(19) United States
(12) Patent Application Publication
(10) Pub. No.: US 2020/0072376 A1
(43) Pub. Date: Mar. 5, 2020

(54) SYSTEM FOR DRIVING AN INDUCTIVE LOAD OF AN APPLIANCE

(71) Applicant: Haier US Appliance Solutions, Inc., Wilmington, DE (US)

(72) Inventor: Mark Anthony Didat, Floyds Knobs, IN (US)

(21) Appl. No.: 16/118,557

(22) Filed: Aug. 31, 2018

(51) Int. Cl. F16K 31/06; D06F 39/08; H01F 7/18; H03K 17/66

(52) U.S. Cl. CPC F16K 31/0675; H03K 17/663; H01F 7/18; D06F 39/085

(57) ABSTRACT

A system for driving an inductive load of an appliance is provided. The system includes a direct current (DC) bus of the appliance. The DC bus is coupled to the inductive load of the appliance. The system includes a transistor having a first terminal, a second terminal, and a third terminal. The first terminal is coupled to the inductive load of the appliance. The second terminal is coupled to ground. The system includes a controller coupled to the third terminal of the transistor. The controller is configured to control operation of the transistor to drive the inductive load of the appliance.

### FIELD

The present subject matter relates generally to controlling operation of an appliance and, more specifically, to driving an inductive load of the appliance.

### BACKGROUND

Generally, washing machine appliances can include a cabinet with a wash tub mounted therein. A wash basket is rotatably mounted within the wash tub and receives articles for washing. During operation of the washing machine appliance, a motor coupled to the wash basket may be powered on while washing fluid (e.g., water and/or detergent) is used to clean articles disposed within the wash basket. For example, after a user makes selections regarding wash and rinse cycles at a control panel, the washing machine operates one or more solenoid valves to fill the wash tub with a certain amount of water. Additives such as detergent and fabric softeners may also be added manually or automatically to the water to form the washing fluid

The one or more solenoid valves of the washing are driven via alternating current (AC) power. Driving these types of inductive loads via AC power requires use of AC switches, such as an electromechanical relay or TRIAC. Since AC switches are cost-prohibitive and inefficient, a need exists for improved systems and methods for driving solenoid valves of a washing machine appliance.

### BRIEF DESCRIPTION

Aspects and advantages of the invention will be set forth in part in the following description, or may be obvious from the description, or may be learned through practice of the invention.

An example aspect of the present disclosure is directed to a system for driving an inductive load of an appliance. The system includes a direct current (DC) bus of the appliance. The DC bus can be coupled to the inductive load of the appliance. The system can include a transistor. The transistor can include a first terminal, a second terminal, and a third terminal. The first terminal can be coupled to the inductive load of the appliance. The second terminal can be coupled to ground. The system can include a controller coupled to the third terminal of the transistor. The controller can be configured to control operation of the transistor to drive the inductive load of the appliance.

Another example aspect of the present disclosure is directed to a washing machine appliance. The washing machine appliance includes a cabinet and a wash tub supported in the cabinet. The washing machine appliance includes a wash basket rotatably mounted in the wash tub and coupled to a motor. The washing machine includes a solenoid valve configured to regulate a flow of water into the wash basket. The washing machine appliance includes a system for driving the solenoid valve. The system includes a direct current (DC) bus of the washing machine appliance. The DC bus is coupled to the solenoid valve and configured to provide DC power to the solenoid valve. The system includes a transistor comprising a first terminal, a second terminal, and a third terminal. The first terminal is coupled to the solenoid valve. The second terminal is coupled to ground. The system includes a controller coupled to the third terminal of the transistor. The controller is configured to control operation of the transistor to drive (e.g., actuate) the solenoid valve.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 depicts a perspective view of a washing machine appliance according to example embodiments of the present disclosure;

FIG. 2 depicts a side, cutaway view of a washing machine appliance according to example embodiments of the present disclosure;

FIG. 3 depicts a schematic of a system for driving an inductive load of an appliance according to example embodiments of the present disclosure; and

FIG. 4 depicts a graphical representation of a voltage measured across the inductive load of FIG. 3 according to example embodiments of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to a system for driving an inductive load of an appliance. The system can include a direct current (DC) bus of the appliance. The DC bus can be coupled to the inductive load of the appliance via one or more conductors. The system can include a transistor and a controller. The transistor can include a first terminal (e.g., a collector), a second terminal (e.g., an emitter), and a third terminal (e.g., a base). The first terminal of the transistor can be coupled to the inductive load via one or more conductors. The second terminal can be coupled to ground via one or more conductors. The third terminal can be coupled to the controller. As will be discussed below, the controller can be configured to control operation of the transistor to drive the inductive load.

In example embodiments, the controller can be configured to control operation of the transistor to pulse width modulate DC power the DC bus provides to the inductive load of the appliance. More specifically, the controller can be configured to selectively activate the transistor to pulse width modulate the DC power the DC bus provides to the inductive load. In example embodiments, the controller can activate (e.g., turn on) the transistor by providing a base current to the third terminal of the transistor. When the transistor is activated, a closed electrical path is provided between the DC bus and ground. In this manner, the DC bus can provide DC power to the inductive load. When the controller stops providing the base current, the transistor deactivates (e.g., turns off) and, as a result, the closed electrical path between the DC bus and ground is no longer present. When no closed electrical path exists between the DC bus and ground, the DC bus cannot provide DC power to the inductive load.

In example embodiments, the appliance is a washing machine, and the inductive load is a solenoid valve of the washing machine. The solenoid valve can be configured to regulate a flow of fluid into a wash basket of the washing machine appliance. More specifically, the solenoid valve can be movable between at least a first position and a second position. When the solenoid valve is in the first position, the solenoid valve can be configured to permit the flow of fluid to flow into the wash basket. When the solenoid valve is in the second position, the solenoid valve can be configured to restrict the flow of fluid into the wash basket.

When the solenoid valve moves to the first position or the second position, the controller can be configured to control operation of the transistor such that the DC power provided to the solenoid valve has a first duty cycle. In contrast, when the solenoid valve is in the first position or the second position, the controller can be configured to control operation of the transistor such that the DC power provided to the solenoid valve has a second duty cycle that is less than the first duty cycle. In this manner, the amount of electrical power the system of the present disclosure consumes to hold the solenoid valve in the first position or the second position can be reduced compared to the amount of electrical power conventional systems using AC switches (e.g., relays, TRIACs) require to hold the solenoid valve in the first position or the second position.

The system of the present disclosure provides numerous technical benefits. For instance, the system does not require AC switches. Additionally, in the context of driving a solenoid valve of the appliance, the amount of electrical power the system of the present disclosure consumes to hold the solenoid in a first position (e.g., fully open) or a second position (e.g., fully closed) is reduced compared to the amount of electrical power consumed by conventional systems using an AC switch. In this manner, the system of the present disclosure can generate less heat compared to conventional systems using the AC switch.

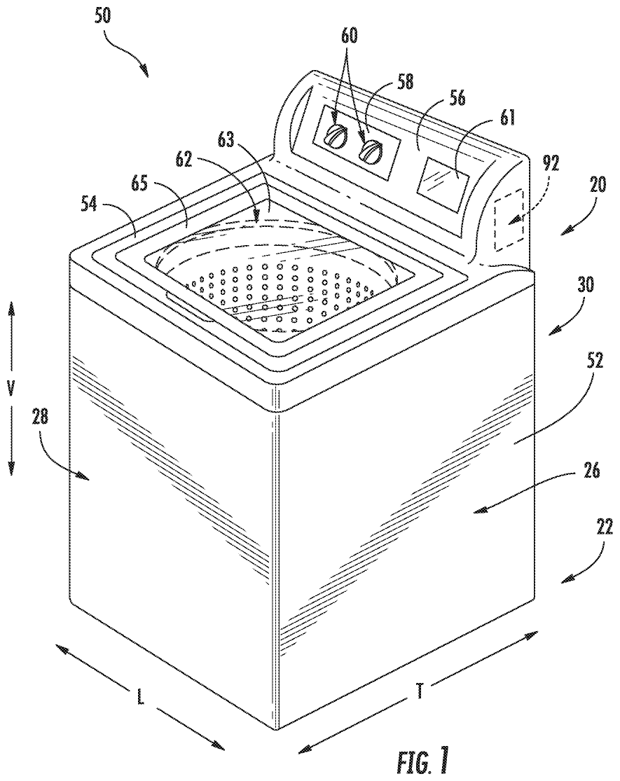

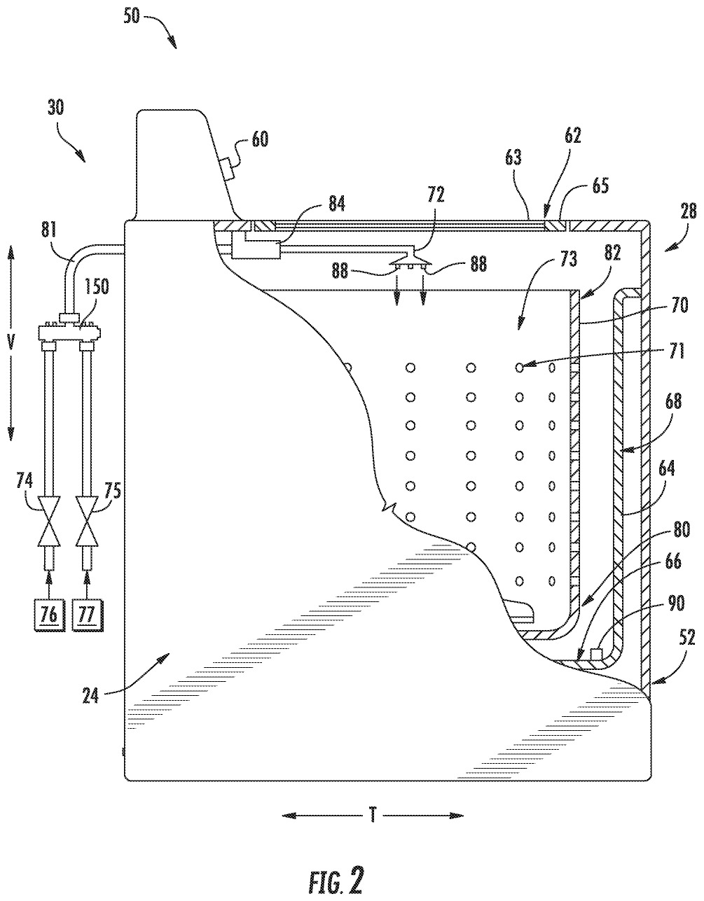

Referring now to the figures, FIGS. 1 and 2 depicts a washing machine appliance 50 according to an exemplary embodiment of the present subject matter. As shown, the washing machine appliance 50 defines an orthogonal coordinate system comprising a vertical direction V, a lateral direction L, and a transverse direction T. Moreover, the washing machine appliance 50 extends generally along the vertical direction V between a top end 20 and a bottom end 22, along the lateral direction L between a first side 24 and a second side 26, and along the transverse direction T between a front side 28 and a rear side 30.

As shown, the washing machine appliance 50 includes a cabinet 52 including a cover 54 and a backsplash 56. The backsplash 56 extends from cover 54, and a control panel 58 including a plurality of input selectors 60 is coupled to the backsplash 56. The control panel 58 and input selectors 60 collectively form a user interface input for operator selection of machine cycles and features. In some embodiments, a display 61 indicates selected features, a countdown timer, and/or other potential items of interest to users. As shown, the washing machine 50 includes a lid 62 mounted to the cover 54. The lid 62 is rotatable between an open position (not shown) and a closed position (shown in FIG. 1). When the lid 62 is in the open position, a user may access a wash tub 64 located within the cabinet 52. However, when the lid 62 is in the closed position, the user may not access the wash tub 64.

In example embodiments, the lid 62 can include a transparent panel 63 formed of, for example, glass, plastic, or any other suitable material. The transparency of panel 63 allows users to see through the panel 63 and into the wash tub 64 when the lid 62 is in the closed position. In certain embodiments, the panel 63 may itself generally form the lid 62. However, in other embodiments, lid 62 may include panel 63 and a frame 65 surrounding and encasing panel 63. Additionally or alternatively, in still other embodiments, the panel 63 may not be transparent.

As shown, the wash tub 64 is positioned within the cabinet 52 and includes a bottom wall 66 and a sidewall 68. A wash drum or wash basket 70 is rotatably mounted within the wash tub 64. In particular, the wash basket 70 is rotatable about the vertical direction V. Thus, the washing machine appliance 50 is generally referred to as a “vertical axis washing machine appliance.” The wash basket 70 defines a wash chamber 73 for receipt of articles for washing and extends, e.g., between a bottom portion 80 and a top portion 82 along the vertical direction V. Additionally, basket 70 defines a plurality of openings or perforations 71 to facilitate fluid communication between an interior of the wash basket 70 and the wash tub 64.

As shown, the washing machine appliance 50 includes a spout 72 configured for flowing a liquid into one or both of the wash tub 64 and wash basket 70. In example embodiments, the spout 72 can be positioned at or adjacent to the top portion 82 of the basket 70. It should be appreciated that the spout 72 is in fluid communication with a water source, or more specifically to a hot water source 76 and a cold water source 77, in order to direct liquid (e.g., water) into the wash tub 64 and/or onto articles within the wash chamber 73 of basket 70. In example embodiments, the spout 72 includes one or more apertures 88 through which water may be sprayed into the wash tub 64. The apertures 88 may, for example, be tubes extending from the spout 72 as illustrated. Alternatively, the apertures 88 may be holes defined in the spout 72. In yet other embodiments, the apertures 88 may be any other suitable openings through which water may be sprayed. Further, the spout 72 may additionally include other openings, holes, etc. (not shown) through which water may be flowed, i.e., sprayed or poured, into the wash tub 64 and/or wash basket 70.

Various valves may regulate the flow of fluid through spout 72 via a supply line 81. For this embodiment, a hot water valve 74 and a cold water valve 75 are positioned along supply line 81 to flow hot water and cold water, respectively, through the supply line 81 fluidly connecting the dual water sources 76, 77 to spout 72. As used herein, the term “supply line” is used to refer generally to the one or more fluid lines, pipes, conduits, etc. provided between water sources 76, 77 and spout 72 of washing machine appliance 50.

The hot water valve 74 and cold water valve 75 may each be selectively adjusted between at least a first position (e.g., an open position) and a second position (e.g., a closed position). When the valves 74, 75 are in the open position, a flow of fluid may flow through the spout 72 and into the wash tub 64 and/or the wash basket 70. When the valves 74, 75 are in the closed position, a flow of fluid cannot flow through the spout 72 and into the wash tub 64 and/or the wash basket 70. The hot water valve 74 is in fluid communication with the hot water source 76, which may be external to the washing machine appliance 50. Similarly, the cold water valve 75 is in fluid communication with the cold water source 77, which may also be external to the washing machine appliance 50. The cold water source 77 may, for example, be a commercial water supply, while the hot water source 76 may be, for example, a water heater appliance. Such water sources 76, 77 may supply water to washing machine appliance 50 through the respective valves 74, 75 and supply line 81.

An additive dispenser 84 is additionally provided for directing a fluid additive, such as detergent, bleach, liquid fabric softener, etc., into the wash tub 64. In example embodiments, the additive dispenser 84 is in fluid communication with spout 72 such that water flowing from supply line 81 to the spout 72 flows through the dispenser 84, mixing with the fluid additive at a desired time during operation to form a liquid or wash fluid, before flowing into the wash tub 64. In some embodiments, the spout 72 is a separate downstream component from the additive dispenser 84. In other embodiments, however, the spout 72 and the additive dispenser 84 may be integral, with a portion of the additive dispenser 84 serving as the spout 72. Alternatively still, the spout 72 and additive dispenser 84 may be separate components defining parallel flow paths from supply line 81 into the wash tub 64 and/or wash basket 70. A pump assembly (not shown) is located beneath the wash tub 64 and wash basket 70 for gravity assisted flow to drain the wash tub 64.

Various sensors may additionally be included in the washing machine appliance 50. For example, a pressure sensor 90 may be positioned in the wash tub 64. Any suitable pressure sensor 90, such as an electronic sensor, a manometer, or another suitable gauge or sensor, may be utilized. The pressure sensor 90 may generally measure the pressure of water in the wash tub 64. This pressure can then be utilized to estimate the height or level of water in the wash tub 64. Additionally, a suitable speed sensor (not shown) can be provided to measure rotational speed of wash basket 70. Other suitable sensors, such as temperature sensors, etc., may additionally be provided in the washing machine appliance 50.

Operation of washing machine appliance 50 is controlled by a controller 92 (shown in phantom in FIG. 1) that is operatively coupled to the input selectors 60 located on the backsplash 56 for user manipulation to select washing machine cycles and features. The controller 92 may further be operatively coupled to various other components of the washing machine appliance 50, such as the valves 74, 75, pressure sensor 90, and other suitable sensors, etc. In response to user manipulation of the input selectors 60, the controller 92 can be configured to operate the various components of washing machine appliance 50 to execute selected machine cycles and features.

The controller 92 can include a memory and microprocessor, such as a general or special purpose microprocessor operable to execute programming instructions or micro-control code associated with a cleaning cycle. The memory may represent random access memory such as DRAM, or read only memory such as ROM or FLASH. In one embodiment, the processor executes programming instructions stored in memory. The memory may be a separate component from the processor or may be included onboard within the processor. Alternatively, the controller 92 may be constructed without using a microprocessor, e.g., using a combination of discrete analog and/or digital logic circuitry (such as switches, amplifiers, integrators, comparators, flip-flops, AND gates, and the like) to perform control functionality instead of relying upon software. The control panel 58 and other components of the washing machine appliance 50 may be in communication with the controller 92 via one or more signal lines or shared communication busses.

In an illustrative aspect of the present disclosure, a load of laundry articles may be loaded into the wash chamber 73 of the wash basket 70 and a washing operation may be initiated through operator manipulation of the control input selectors 60. Upon initiating the washing operation, the wash tub 64 can be filled with water and mixed with detergent to form a liquid or wash fluid. The valves 74, 75 can be opened to initiate a flow of water into wash tub 64 via the spout 72, and the wash tub 64 can be filled to the appropriate level based, at least in part, on the amount of articles being washed. Once the wash tub 64 is properly filled with wash fluid, the contents of the basket 70 are agitated with an agitation element (not shown) or by movement of the wash basket 70 to facilitate cleaning of the one or more clothing articles disposed within the wash basket 70. For example, the agitation element and/or wash basket 70 may be moved back and forth in an oscillatory motion.

After the agitation phase of the wash cycle is completed, the wash tub 64 is drained. Laundry articles can then be rinsed by again adding fluid to the wash tub 64, and depending on the particulars of the cleaning cycle selected by a user, the agitation element and/or the wash basket 70 may again provide agitation within the wash basket 70. One or more spin cycles may also be used. In particular, a spin cycle may be applied after the wash cycle and/or after the rinse cycle in order to wring wash fluid from the articles being washed. During a spin cycle, the wash basket 70 is rotated at relatively high speeds.

While described in the context of a specific embodiment of a vertical axis washing machine appliance 50, using the teachings disclosed herein it will be understood that the vertical axis washing machine appliance 50 is provided by way of example only. Other washing machine appliances having different configurations, different appearances, and/or different features may also be utilized with the present subject matter as well, e.g., horizontal axis washing machine appliances. In addition, the teachings disclosed herein may be used with other appliances as well, e.g., a dishwasher appliance, a cooking range appliance, a garbage disposal appliance, and other suitable appliances.

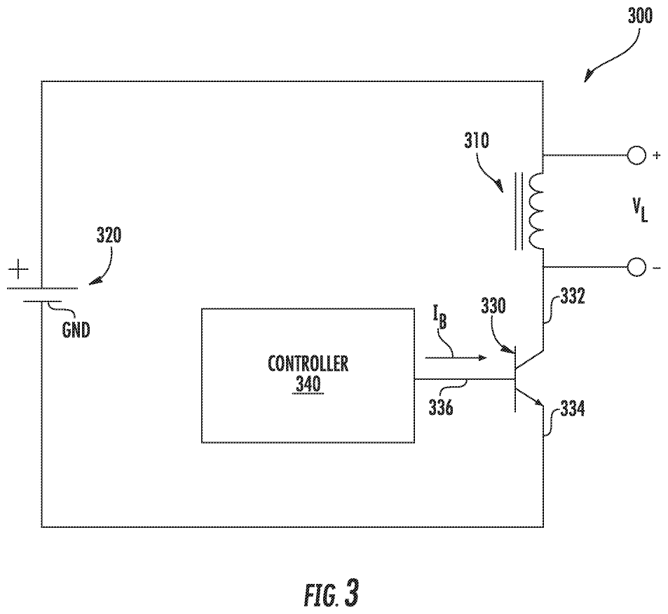

Referring now to FIG. 3, a system 300 for driving an inductive load 310 of an appliance is provided according to example embodiments of the present disclosure. In example embodiments, the inductive load 310 can include a solenoid valve (e.g., valves 74, 75 of FIG. 1). More specifically, the solenoid valve can be an AC solenoid valve or a DC solenoid valve. It should be appreciated, however, that scope of the present disclosure is intended to cover any suitable type of inductive load of the appliance. It should also be appreciated that the appliance can be any suitable type of appliance. For instance, in some embodiments, the appliance can be a washing machine appliance, such as the washing machine appliance discussed above with reference to FIGS. 1 and 2. Alternatively, the appliance can be a dishwashing appliance.

As shown, the system 300 includes a direct current (DC) bus 320. In example embodiments, the DC bus 320 can be associated with a power converter or inverter of the appliance. For example, the DC bus 320 can be associated with a power converter configured to convert alternating current (AC) power to DC power. Alternatively, the DC bus 320 can be associated with a power inverter configured to convert DC power to AC power. It should be appreciated that the DC bus 320 can be configured to provide any suitable DC voltage. For instance, in some embodiments, the DC bus 320 can be a high voltage DC bus configured to provide DC voltage greater than 100 Volts. As will be discussed below in more detail, the DC bus 320 can provide DC power to the inductive load 310 of the appliance.

As shown, the system 300 can include a transistor 330 having a first terminal 332 (e.g., a collector), a second terminal 334 (e.g., an emitter), and a third terminal 336 (e.g., a base). The first terminal 332 can be coupled to the inductive load 310. In example embodiments, the system 300 can include a first resistor coupled between the inductive load 310 and the first terminal 332 of the transistor 330. As shown, the second terminal 434 can be coupled to a ground reference GND. In example embodiments, the system 300 can include a second resistor coupled between the ground reference GND and the second terminal 334 of the transistor 330. As shown, the third terminal 336 can be coupled to a controller 340, such as the controller 92 of the washing machine appliance discussed above with reference to FIGS. 1 and 2. In example embodiments, the system 300 can include a third resistor coupled between the controller 340 and the third terminal 336 of the transistor 330.

It should be appreciated that the transistor 330 can include any suitable type of transistor. For instance, in some embodiments, the transistor 330 can be a bipolar junction transistor (BJT). More specifically, the BJT can be a negative-positive-negative (NPN) type transistor. Alternatively, the BJT can be a positive-negative-positive (PNP) type transistor. In other embodiments, the transistor 330 can be a metal-oxide field effect transistor (MOSFET). As will be discussed below in more detail, the controller 92 can be configured to control operation of the transistor 330 to drive the inductive load 310.

In example embodiments, the controller 340 can be configured to control operation of the transistor 330 to pulse width modulate the DC power the DC bus 320 provides to the inductive load 310. More specifically, the controller 340 can be configured to selectively activate the transistor 330 to pulse width modulate the DC power the DC bus 320 provides to the inductive load 310 of the appliance. In example embodiments, the controller 340 can activate (e.g., turn on) the transistor 330 by providing a current I_{B} to the third terminal 336. When the transistor 330 is activated, a closed electrical path is provided between the DC bus 320 and ground GND. In this manner, the DC bus 320 can provide DC power to the inductive load 310 of the appliance. When the controller 340 stops providing the current I_{B}, the transistor 330 is deactivated (e.g., turned off). As such, the closed electrical path between the DC bus 320 and ground GND is no longer present. In this manner, the DC bus 320 can no longer provide DC power to the inductive load 310. In some embodiments, the system 300 can include a diode (not shown) coupled across the inductive load 310. The diode can protect the transistor 330 against a voltage spike that occurs across the inductive load 310 of the appliance each time the transistor 330 is deactivated.

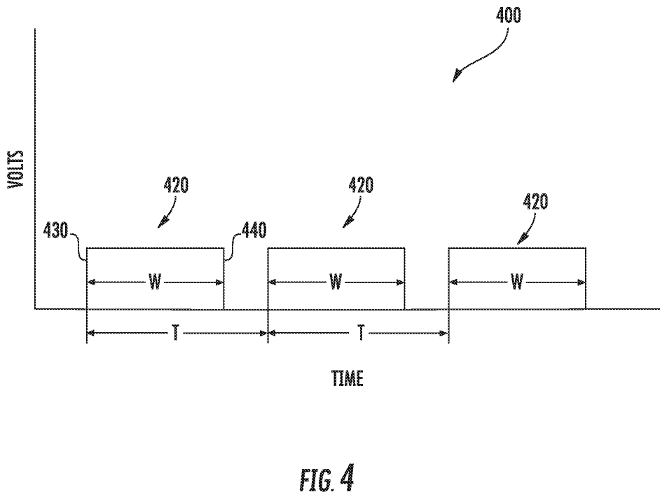

FIG. 4 depicts a graph of a time-varying voltage signal 400 indicative of a voltage V_{L} (FIG. 3) measured across the inductive load 310 (FIG. 3) for a period of time. As shown, the time-varying voltage signal 400 includes a plurality of pulses 420. Each pulse of the plurality of pulses 420 includes a rising edge 430 and a falling edge 440. The rising edge 430 indicates activation of the transistor 330 (FIG. 3). In contrast, the falling edge 440 indicates deactivation of the transistor 330 (FIG. 3). It should be appreciated that a width W of each pulse of the plurality of pulses 420 indicates an amount of time the transistor is active (that is, receiving the current I_{B}). It should be appreciated that a duty cycle of the voltage signal 400 can be determined based, at least in part, on the width W of a pulse and the period T. As shown, the period T corresponds to an amount of time between a rising edge 430 of a first pulse and a rising edge 430 of a second pulse that is the next pulse to occur after the first pulse.

Referring again to FIG. 3, the inductive load 310 can, as discussed above, be a solenoid valve of a washing machine appliance, such as the washing machine depicted in FIGS. 1 and 2. In example embodiments, the solenoid valve (e.g., valve 74, 75 of FIG. 1) can be configured to regulate a flow of fluid into a wash basket (e.g., wash basket 70 of FIG. 1). More specifically, the solenoid valve can be movable between at least a first position and a second position. When the solenoid valve is in the first position, the solenoid valve can be configured to permit the flow of fluid into the wash basket. When the solenoid valve is in the second position, the solenoid valve can be configured to prohibit the flow of fluid into the wash basket.

When the solenoid valve is moving to the first position or the second position, the controller 340 can be configured to control operation of the transistor 330 such that the DC power provided to the solenoid valve has a first duty cycle. In this manner, the duty cycle of the voltage signal 400 (FIG. 4) indicative of the voltage V_{L} across the solenoid valve can correspond to the first duty cycle. In contrast, when the solenoid valve is in the first position or the second position, the controller 340 can be configured to control operation of the transistor 330 such that the DC power provided to the solenoid valve has a second duty cycle that is less than the first duty cycle. In this manner, the duty cycle of the voltage signal 400 (FIG. 4) indicative of the voltage V_{L} across the solenoid valve can correspond to the second duty cycle.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A system for driving an inductive load of an appliance, the system comprising:
a direct current (DC) bus of the appliance, the DC bus coupled to the inductive load of the appliance;
a transistor comprising a first terminal, a second terminal, and a third terminal, the first terminal coupled to the inductive load of the appliance, the second terminal coupled to ground; and
a controller coupled to the third terminal of the transistor, the controller configured to control operation of the transistor to drive the inductive load of the appliance.

2. The system of claim 1, wherein the controller is configured to selectively activate the transistor to pulse width modulate DC power the DC bus provides to the inductive load of the appliance.

3. The system of claim 1, wherein the DC bus is associated with a power inverter of the appliance.

4. The system of claim 1, wherein the DC bus is associated with a power converter of the appliance.

5. The system of claim 1, wherein the transistor comprises a bipolar junction transistor (BJT).

6. The system of claim 5, wherein the BJT is a negative-positive-negative (NPN) type transistor.

7. The system of claim 5, wherein the BJT is a positive-negative-positive (PNP) type transistor.

8. The system of claim 1, wherein the inductive load of the appliance comprises a solenoid valve.

9. The system of claim 8, wherein the solenoid valve comprises an alternating current (AC) solenoid valve.

10. The system of claim 8, wherein the solenoid valve comprises a direct current (DC) solenoid valve.

11. The system of claim 1, wherein the transistor comprises a metal oxide field effect transistor (MOSFET).

12. The system of claim 11, wherein the inductive load of the appliance comprises a solenoid valve.

13. A washing machine appliance, comprising:
a cabinet;
a wash tub supported in the cabinet;
a wash basket rotatably mounted in the wash tub and coupled to a motor;
a solenoid valve configured to regulate a flow of fluid into the wash basket; and
a system for driving the solenoid valve, the system comprising:
a direct current (DC) bus of the washing machine, the DC coupled to the solenoid valve;
a transistor comprising a first terminal, a second terminal, and a third terminal, the first terminal coupled to the solenoid valve, the second terminal coupled to ground; and
a controller coupled to the third terminal of the transistor the controller configured to control operation of the transistor to drive the solenoid valve.

14. The washing machine of claim 13, wherein the controller is configured to selectively activate the transistor to pulse width modulate DC power the DC bus provides to the solenoid valve.

15. The washing machine of claim 13, wherein the transistor comprises a bipolar junction transistor.

16. The washing machine of claim 15, wherein bipolar junction transistor is a negative-positive-negative type transistor.

17. The washing machine of claim 15, wherein the bipolar junction transistor is a positive-negative-positive type transistor.

18. The washing machine of claim 13, wherein the solenoid valve is movable between at least a first position and a second position, wherein when the solenoid valve is in the first position, the solenoid valve is configured to permit the flow of fluid into the wash basket, and wherein when the solenoid valve is in the second position, the solenoid valve is configured to prevent the flow of fluid into the wash basket.

19. The washing machine of claim 18, wherein when the solenoid valve is moving to the first position or the second position, the controller is configured to control operation of the transistor such that the DC power provided to the solenoid valve has a first duty cycle; and wherein when the solenoid valve is in the first position or the second position, the controller is configured to control operation of the transistor such that the DC power provided to the solenoid valve has a second duty cycle that is less than the first duty cycle.
